(19) United States
(12) Patent Application Publication
(10) Pub. No.: US 2015/0253632 A1
(43) Pub. Date: Sep. 10, 2015

(54) MANUFACTURING METHOD OF PHOTO-ALIGNMENT FILM

(71) Applicants: INNOCOM TECHNOLOGY (SHENZHEN) CO., LTD., Shenzhen City (CN); INNOLUX CORPORATION, Jhu-Nan (TW)

(72) Inventors: Chung-Yi WANG, Jhu-Nan (TW); An-Chang WANG, Jhu-Nan (TW); Shiang-Ruei OUYANG, Jhu-Nan (TW)

(21) Appl. No.: 14/721,985

(22) Filed: May 26, 2015

Related U.S. Application Data
(62) Division of application No. 13/604,558, filed on Sep. 5, 2012.

(30) Foreign Application Priority Data
Sep. 7, 2011 (TW) 100132199

(51) Int. Cl. G02F 1/1337; G03F 7/20

(52) U.S. Cl. CPC G02F 1/133788; G03F 7/20

(57) ABSTRACT

A manufacturing method of a photo-alignment film is provided, which includes: providing a photo-alignment material layer having at least one portion corresponding to a pixel; and performing a full exposure process and a partial exposure process with an alignment direction different from that of the full exposure process to the portion, wherein the full exposure process includes exposing the portion fully to light, and the partial exposure process includes exposing the portion partially to light, wherein the portion processed by the exposure processes has a single exposure region exposed to light one time and a dual exposure region exposed to light two times, and the portion exposed in the partial exposure process is located in the dual exposure region.

### CROSS REFERENCE TO RELATED APPLICATIONS

This application is a Divisional of pending U.S. patent application Ser. No. 13/604,558, filed on Sep. 5, 2012 and entitled “Photo-alignment film and manufacturing method thereof”, which claims priority of Taiwan Patent Application No. 100132199, filed on Sep. 7, 2011, the entirety of which is incorporated by reference herein.

### BACKGROUND

1. Technical Field

The disclosure relates to a liquid crystal display, and in particular relates to a photo-alignment film and manufacturing methods thereof.

2. Description of the Related Art

A liquid crystal display is composed of an active device array substrate, an opposite substrate, and a liquid crystal layer. When an electric field is applied between the opposite substrate and the active device array substrate, liquid crystal molecules of the liquid crystal layer are tilted by the effect of the electric field, such that the liquid crystal layer has a light transmittance corresponding to the electric field. As such, the liquid crystal display displays different gray level frames according to the electric field between the opposite substrate and the active device array substrate. For the purpose of fast response of the liquid crystal molecules and satisfaction of wide viewing angle needs, the liquid crystal molecules in a plurality of areas are tilted in different directions, i.e. multi-domain alignment.

Presently, in order to cause the liquid crystal molecules to be arranged in a multi-domain pattern, the most common method generally includes the deposition of protrusions, changing of the fringe field, or photo alignment methods. The changing of the fringe field results in a complicated manufacturing process, and the deposition of protrusions decreases the aperture rate of the display region. To avoid the above two disadvantages, the photo alignment methods may be used to form the multi-domain alignment.

The multi-domain photo-alignment technology includes performing exposure processes by using linearly polarized ultraviolet light, such that the photo-alignment film of the liquid crystal display has a plurality of alignment directions. However, the multi-domain photo-alignment technology needs to use a plurality of expensive photomasks for the alignment film to have a plurality of alignment directions, which significantly increases the manufacturing cost.

### BRIEF SUMMARY

An embodiment of the disclosure provides a manufacturing method of a photo-alignment film which includes: providing a photo-alignment material layer having at least one pixel-corresponding region; and performing a full exposure process and a partial exposure process with an alignment direction different from that of the full exposure process to the pixel-corresponding region, wherein the full exposure process includes exposing the pixel-corresponding region fully to light, and the partial exposure process includes exposing a portion of the pixel-corresponding region to light.

An embodiment of the disclosure provides a photo-alignment film, which includes: at least one pixel-corresponding region only having a single exposure region exposed to light one time and a dual exposure region exposed to light two times, wherein a portion of the pixel-corresponding region in the single exposure region has a first alignment direction and a pre-tilt angle, and a portion of the pixel-corresponding region in the dual exposure region has a second alignment direction different from the first alignment direction and the pre-tilt angle.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1A to FIG. 1B are top views of a manufacturing process of a photo-alignment film known to the inventor;

FIG. 2A to FIG. 2B are cross-sectional views of the structure along the line I-I′ in FIG. 1A to FIG. 1B respectively;

FIG. 3A to FIG. 3C are top views of a manufacturing process of a photo-alignment film according to an embodiment of the disclosure;

FIG. 4A to FIG. 4B are cross-sectional views of the structure along the line I-I′ in FIG. 3A to FIG. 3B respectively, and FIG. 4C is a cross-sectional view of the structure along the line II-II′ in FIG. 3C, and FIG. 4C further depicts liquid crystal molecules on the photo-alignment material layer;

FIG. 5A is a top view of a manufacturing process of a photo-alignment film according to another embodiment of the disclosure;

FIG. 5B is a cross-sectional view of the structure along the line I-I′ in FIG. 5A;

FIGS. 6A to 6C are top views of a manufacturing process of a photo-alignment film according to an embodiment of the disclosure;

FIG. 7A to FIG. 7B are cross-sectional views of the structure along the line I-I′ in FIG. 6A to FIG. 6B respectively, and FIG. 7C is a cross-sectional view of the structure along the line II-II′ in FIG. 6C, and FIG. 7C further depicts liquid crystal molecules on the photo-alignment material layer;

FIG. 8A is a top view of a manufacturing process of a photo-alignment film according to another embodiment of the disclosure;

FIG. 8B is a cross-sectional view of the structure along the line I-I′ in FIG. 8A; and

FIG. 9 is a cross-sectional view of a liquid crystal display according to an embodiment of the disclosure.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

It should be understood, that the following disclosure provides many different embodiments, or examples, for implementing different features of the disclosure. Specific examples of components and arrangements are described below to simplify the disclosure. These are, of course, merely examples and are not intended to be limiting. In addition, the disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

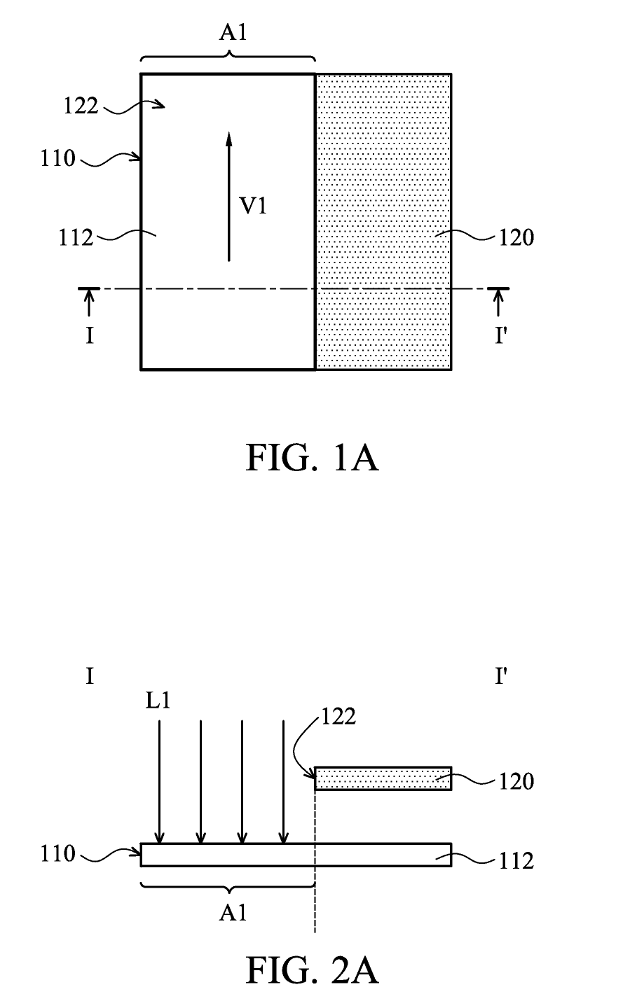

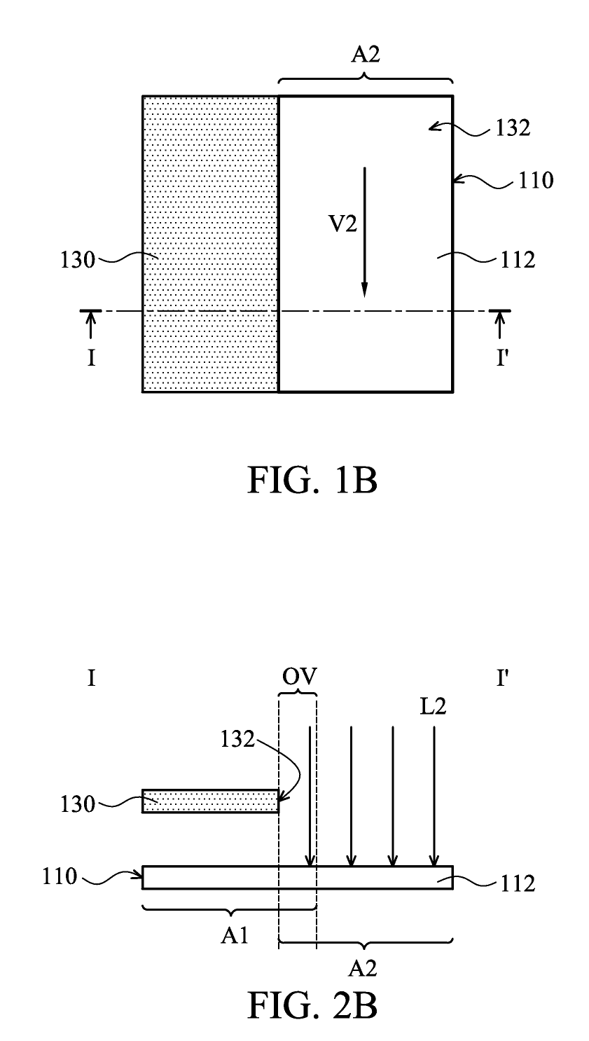

FIG. 1A to FIG. 1B are top views of a manufacturing process of a photo-alignment film known to the inventor. FIG. 2A to FIG. 2B are cross-sectional views of the structure along the line I-I′ in FIG. 1A to FIG. 1B respectively. It should be noted that the embodiment of FIGS. 1A, 1B, 2A, and 2B merely illustrate a manufacturing method of a photo-alignment film used in a liquid crystal display known to the inventor, and should not be construed as an admission that such a method is publicly known or otherwise part of the prior art. Also, for simplicity sake, FIG. 1A and FIG. 1B omit the outer frame of the opening of a photomask.

Referring to FIGS. 1A and 2A, a photo-alignment material layer 110 used in a liquid crystal display is provided, wherein the photo-alignment material layer 110 has a plurality of pixel-corresponding regions 112. Each of the pixel-corresponding regions 112 corresponds to a pixel of the liquid crystal display to control pre-tilt angles and alignment directions of liquid crystal molecules of the pixel. It should be noted that, for simplicity sake, only one pixel-corresponding region 112 and its manufacturing processes (e.g., a photomask, or the light used for exposure) are shown.

Then, a first photomask 120 is disposed on the pixel-corresponding region 112, and an opening 122 of the first photomask 120 exposes a first region A1 of the pixel-corresponding region 112. A first exposure process is performed on the first region A1 by using the first photomask 120 as a mask, such that the portion of the pixel-corresponding region 112 in the first region A1 has a first alignment direction V1 and a first pre-tilt angle. In this case, the “pre-tilt angle” means an included angle between a major axis direction of a liquid crystal molecule and a main surface of the photo-alignment material layer.

Then, referring to FIGS. 1B and 2B, the first photomask 120 is removed, and a second photomask 130 is disposed on the pixel-corresponding region 112. An opening 132 of the second photomask 130 exposes a second region A2 of the pixel-corresponding region 112. A second exposure process is performed on the second region A2 by using the second photomask 130 as a mask, such that the portion of the pixel-corresponding region 112 in the second region A2 has a second alignment direction V2 and a second pre-tilt angle. There is an overlap area OV between the first region A1 and the second region A2. Then, the second photomask 130 is removed.

It should be noted that, in the first exposure process and the second exposure process, there are inevitable misalignments between the first photomask 120 and the pixel-corresponding region 112 and between the second photomask 130 and the pixel-corresponding region 112. The misalignments may cause separation or partial overlap of the first region A1 and the second region A2, which results in poor alignment in a portion of the pixel-corresponding region 112. This poor alignment results in the hindering of the fast response of the liquid crystal molecules, thereby negatively impacting the display performance of the liquid crystal display.

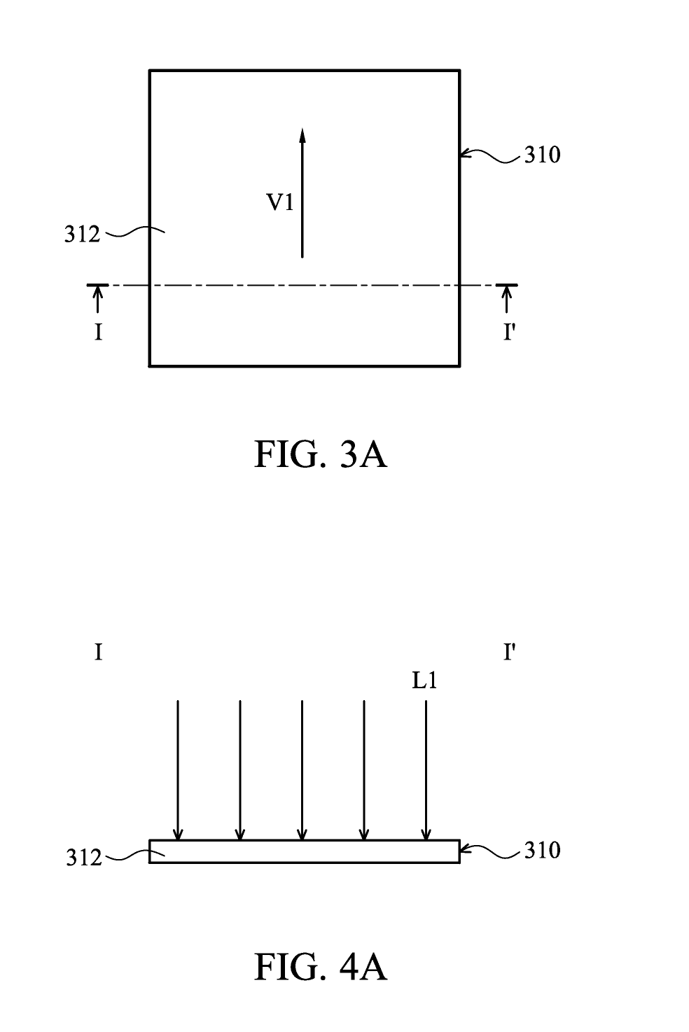

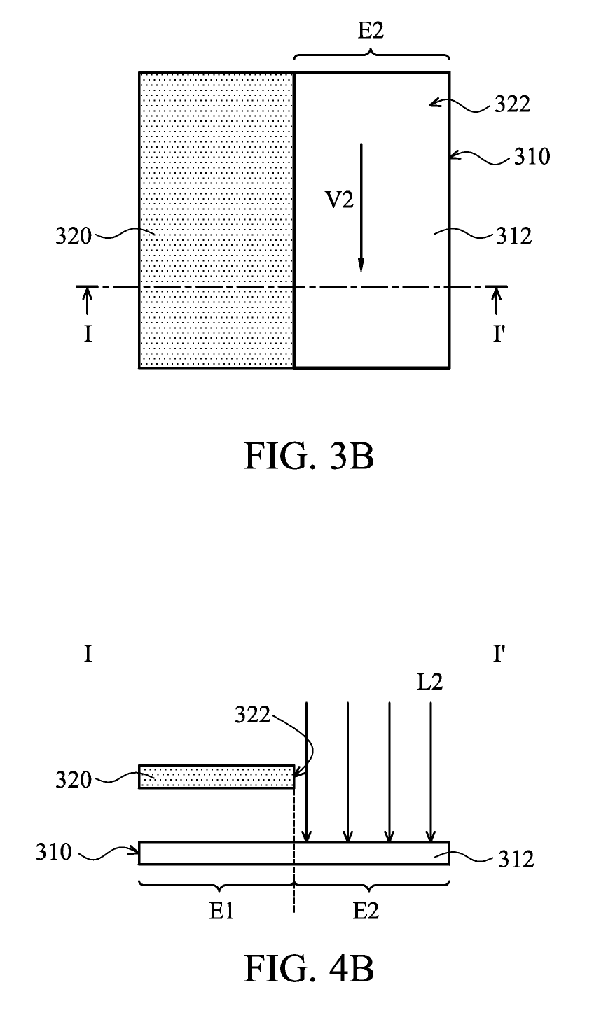

FIG. 3A to FIG. 3C are top views of a manufacturing process of a photo-alignment film according to an embodiment of the disclosure. FIG. 4A to FIG. 4B are cross-sectional views of the structure along the line I-I′ in FIG. 3A to FIG. 3B respectively. FIG. 4C is a cross-sectional view of the structure along the line II-II′ in FIG. 3C, and FIG. 4C further depicts liquid crystal molecules on the photo-alignment material layer. For simplicity sake, FIG. 3B omits the outer frame of an opening of a photomask.

Firstly, referring to FIG. 3A and FIG. 4A, a photo-alignment material layer 310 suitable to be used in a liquid crystal display is provided. The material of the photo-alignment material layer 310 is, for example, polyimide (PI) or other suitable photo-alignment materials. In the disclosure, the material of the photo-alignment material layer 310 is a photo-alignment material dominated by the second photo-alignment.

The photo-alignment material layer 310 has a plurality of pixel-corresponding regions 312. Each of the pixel-corresponding regions 312 corresponds to a pixel of the liquid crystal display to control pre-tilt angles and alignment directions of liquid crystal molecules of the pixel. It should be noted that, for simplicity sake, only one pixel-corresponding region 312 and its manufacturing processes (e.g., a photomask, or the light used for exposure) are shown. It can be readily appreciated by those with ordinary skill in the art that the manufacturing process of the disclosure also can be performed on other pixel-corresponding regions, which are not shown.

Then, a full exposure process is performed on the pixel-corresponding region 312 which has not been exposed to light, such that the pixel-corresponding region 312 has a first alignment direction V1 and a first pre-tilt angle θ1, as shown by FIG. 4C. Specifically, the full exposure process includes exposing the pixel-corresponding region 312 fully to a first light L1. In one embodiment, as shown in FIGS. 3A and 4A, the performing of the full exposure process includes directly exposing the entirety of the photo-alignment material layer 310 to the first light L1 without using a photomask.

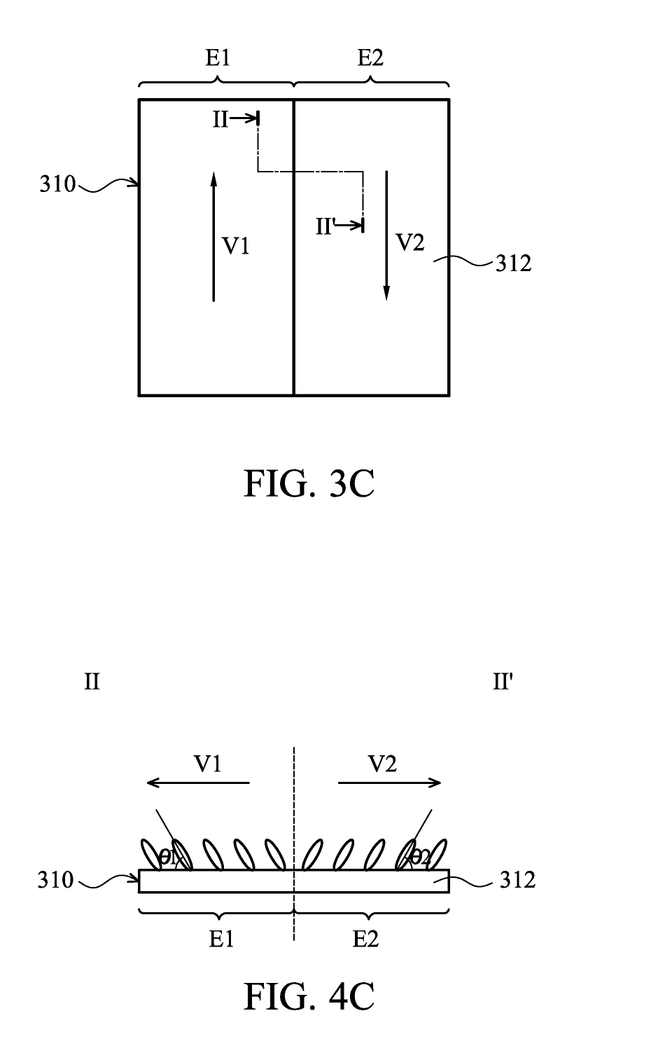

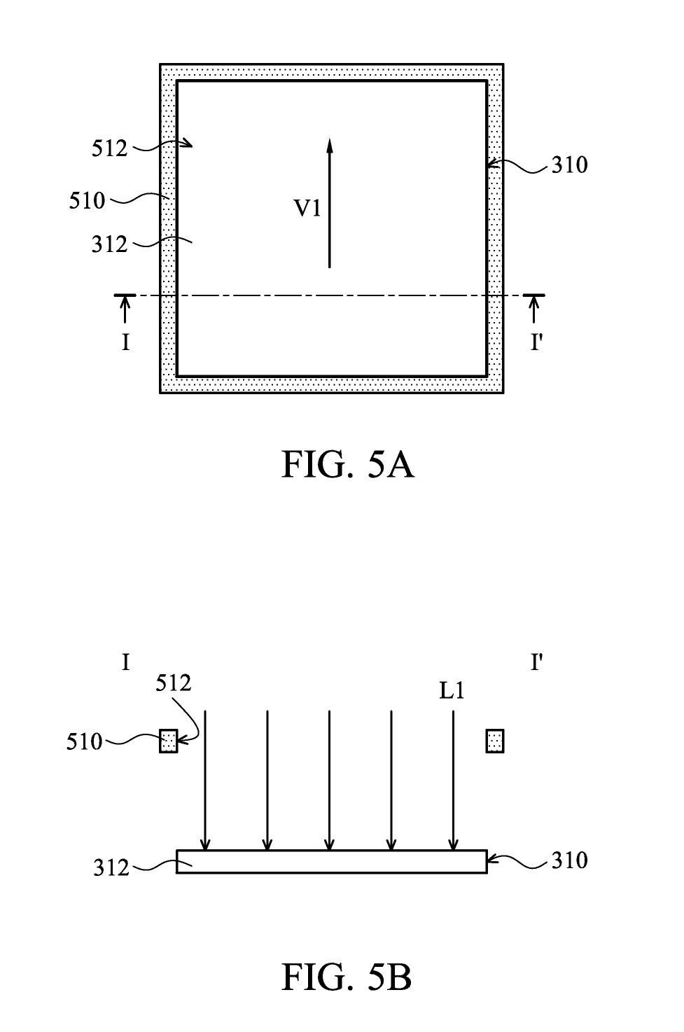

FIG. 5A is a top view of a manufacturing process of a photo-alignment film according to another embodiment of the disclosure. FIG. 5B is a cross-sectional view of the structure along the line I-I′ in FIG. 5A. In another embodiment, as shown in FIGS. 5A and 5B, the performing of the full exposure process may include disposing a photomask 510 on the pixel-corresponding region 312, wherein the photomask 510 has an opening 512 fully exposing the pixel-corresponding region 312, and then, exposing the pixel-corresponding region 312 fully to light by using the photomask 510. The opening 512 may expose a plurality of pixel-corresponding regions at the same time, or may expose the entirety of the photo-alignment material layer 310.

Then, referring to FIGS. 3B and 4B, a photomask 320 is disposed on the pixel-corresponding region 312, wherein the photomask 320 has an opening 322 merely exposing a portion of the pixel-corresponding region 312. Then, by using the photomask 320 as a mask, a partial exposure process is performed on the pixel-corresponding region 312 for the portion of the pixel-corresponding region 312 to have a second alignment direction V2 and a second pre-tilt angle θ2, as shown in FIG. 4C. Specifically, the partial exposure process exposes only the portion of the pixel-corresponding region 312 to a second light L2, and the first alignment direction V1 is different from the second alignment direction V2.

It should be noted that, because the photo-alignment material layer 310 of the present embodiment employs the photo-alignment material dominated by the second photo-alignment, in the pixel-corresponding region 312 sequentially processed by the full exposure process and the partial exposure process, the portion exposed in the partial exposure process is dominated by the partial exposure process (i.e. the second photo-alignment) to have the second alignment direction V2 and the second pre-tilt angle θ2, as shown in FIG. 4C.

Then, referring to FIGS. 3C and 4C, the photomask 320 is removed. The pixel-corresponding region 312 processed by the full exposure process and the partial exposure process has a single exposure region E1 exposed to light one time and a dual exposure region E2 exposed to light two times, and the single exposure region E1 connects to the dual exposure region E2. Specifically, as shown in FIG. 4B, in the partial exposure process, the portion of the pixel-corresponding region 312 exposed to light (i.e., the portion exposed by the opening 322) is located in the dual exposure region E2, and the portion of the pixel-corresponding region 312 shielded by the photomask 320 is located in the single exposure region E1.

In this case, the portion of the pixel-corresponding region 312 in the single exposure region E1 has the first alignment direction V1 and the first pre-tilt angle θ1, and the portion of the pixel-corresponding region 312 in the dual exposure region E2 has the second alignment direction V2 and the second pre-tilt angle θ2. In one embodiment, the first alignment direction V1 is opposite to the second alignment direction V2. The first pre-tilt angle θ1 is, for example, substantially equal to the second pre-tilt angle θ2. The area of the single exposure region E1 is, for example, substantially equal to the area of the dual exposure region E2. In one embodiment, a ratio of the exposed area of the pixel-corresponding region 312 in the partial exposure process (i.e., the area of the dual exposure region E2) to the exposed area of the pixel-corresponding region 312 in the full exposure process (i.e., the total area of the single exposure region E1 and the dual exposure region E2) is about 0.3 to 0.7. In other words, the ratio of the area of the single exposure region E1 to the area of the dual exposure region E2 is about 3:7 to 7:3 (i.e., the ratio is about 0.428 to 2.333).

In one embodiment, in a unit area of the photo-alignment material layer 310 exposed to light, a total light exposure energy applied by the partial exposure process is larger than that of the full exposure process. For example, a light exposure intensity of the partial exposure process may be larger than that of the full exposure process, or a light exposure time of the partial exposure process may be longer than that of the full exposure process.

Because the sensibility of the photo-alignment material to subsequent exposure processes may decrease after being processed by the exposure process one time, the total light exposure energy applied by the partial exposure process may be increased to increase the second pre-tilt angle θ2 to be substantially equal to the first pre-tilt angle θ1. In one embodiment, the first pre-tilt angle θ1 is substantially equal to the second pre-tilt angle θ2, and the first alignment direction V1 is opposite to the second alignment direction V2.

It should be noted that, the present embodiment employs a full exposure process and a partial exposure process to replace the two partial exposure processes of the manufacturing method of FIGS. 1A and 1B. The full exposure process can be performed without using any photomask, which can effectively prevent the problem of misalignment and can significantly lower the manufacturing cost. Furthermore, by the combination of the full exposure process and the partial exposure process, the formation of only two alignment regions with substantially the same pre-tilt angle and different alignment directions can be easily achieved, which can prevent the problem that an overlap region is produced by the manufacturing method of FIGS. 1A and 1B so as to improve the fast response of the liquid crystal molecules, and thus, the display performance of the liquid crystal display.

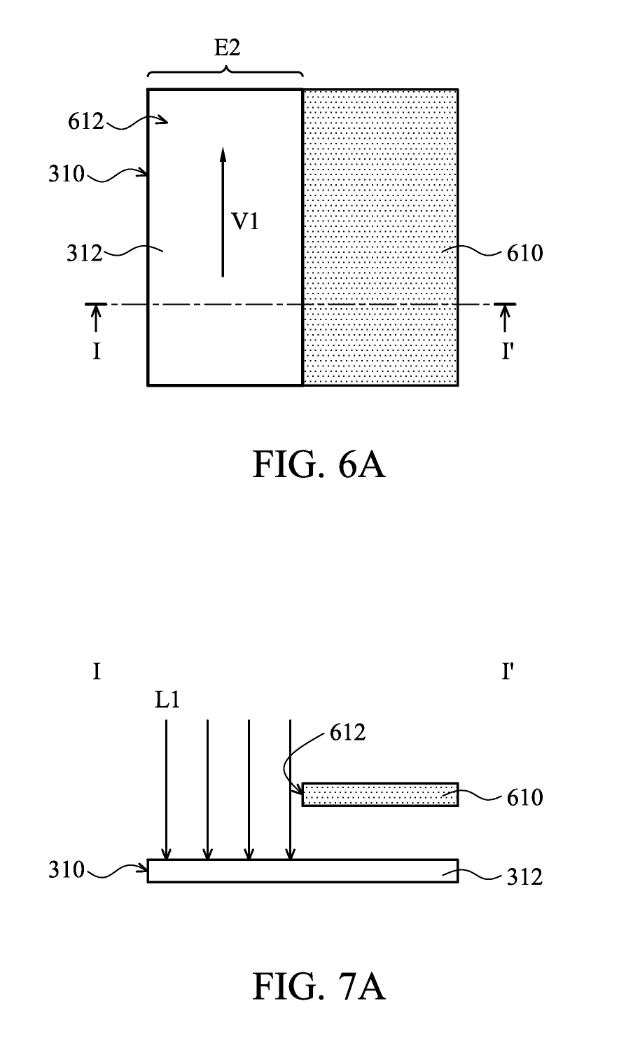

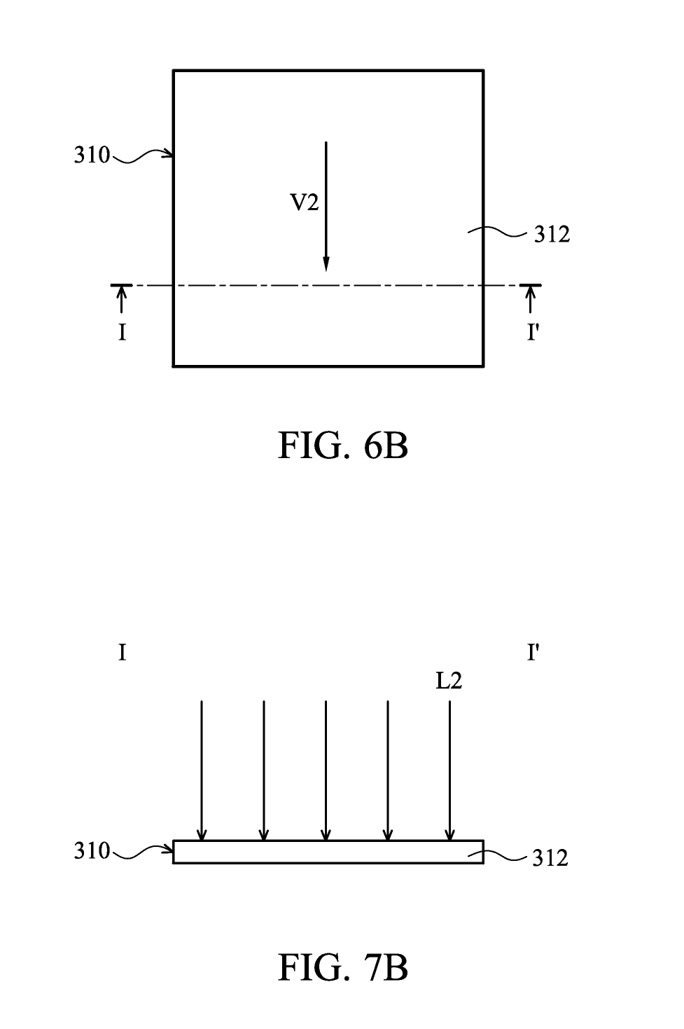

FIGS. 6A to 6C are top views of a manufacturing process of a photo-alignment film according to an embodiment of the disclosure. FIG. 7A to FIG. 7B are cross-sectional views of the structure along the line IT in FIG. 6A to FIG. 6B respectively. FIG. 7C is a cross-sectional view of the structure along the line II-II′ in FIG. 6C, and FIG. 7C further depicts liquid crystal molecules on the photo-alignment material layer. For simplicity sake, FIG. 6A omits a frame of an opening of a photomask.

It should be noted that the present embodiment is similar to the embodiment of FIGS. 3A to 3C, except that the photo-alignment material layer 310 of the present embodiment includes the photo-alignment material dominated by the first photo-alignment, and as such the sequence of the performing of the full exposure process and the partial exposure process is opposite to that of the embodiment of FIGS. 3A to 3C. Elements designed by the same reference numbers as those in FIGS. 3A to 3C have the structures and the materials similar thereto. Therefore, the detailed descriptions thereof will not be repeated herein.

Firstly, referring to FIGS. 6A and 7A, a photo-alignment material layer 310 having a plurality of pixel-corresponding regions 312 is provided. It should be noted that, for simplicity sake, only one pixel-corresponding region 312 and its manufacturing processes (e.g., a photomask, or the light used for exposure) are shown. It can be readily appreciated by those with ordinary skill in the art that the manufacturing process of the present embodiment also can be performed on other pixel-corresponding regions, which are not shown.

Then, a photomask 610 is disposed on the pixel-corresponding region 312, and the photomask 610 has an opening 612 merely exposing a portion of the pixel-corresponding region 312. Then, by using the photomask 610 as a mask, a partial exposure process is performed on the pixel-corresponding region 312 which has not been exposed to light, such that a portion of the pixel-corresponding region 312 has a first alignment direction V1 and a first pre-tilt angle θ1, as shown by FIG. 7C. Specifically, the partial exposure process exposes only the portion of the pixel-corresponding region 312 to a first light L1.

Then, referring to FIGS. 6B and 7B, the photomask 610 is removed. Then, a full exposure process is performed on the pixel-corresponding region 312, such that the pixel-corresponding region 312, except the portion which was exposed to light in the partial exposure process, has a second alignment direction V2 and a second pre-tilt angle θ2, as shown in FIG. 7C. Specifically, the full exposure process includes exposing the entirety of the pixel-corresponding region 312 to a second light L2. In one embodiment, as shown in FIGS. 6B and 7B, the performing of the full exposure process includes directly fully exposing the photo-alignment material layer 310 to light without using a photomask.

Then, as shown in FIGS. 6C and 7C, because the photo-alignment material layer 310 of the present embodiment employs the photo-alignment material dominated by the first photo-alignment, in the pixel-corresponding region 312 sequentially processed by the partial exposure process and the full exposure process, the portion exposed in the partial exposure process is dominated by the partial exposure process (i.e. the first photo-alignment) to have the first alignment direction V1 and the first pre-tilt angle θ1.

The pixel-corresponding region 312 processed by the partial exposure process and the full exposure process has a single exposure region E1 exposed to light one time and a dual exposure region E2 exposed to light two times, and the single exposure region E1 connects to the dual exposure region E2.

In this case, the portion of the pixel-corresponding region 312 in the single exposure region E1 has the second alignment direction V2 and the second pre-tilt angle θ2, and the portion of the pixel-corresponding region 312 in the dual exposure region E2 has the first alignment direction V1 and the first pre-tilt angle θ1. In one embodiment, the first alignment direction V1 is opposite to the second alignment direction V2. The first pre-tilt angle θ1 is, for example, substantially equal to the second pre-tilt angle θ2. The area of the single exposure region E1 is, for example, substantially equal to the area of the dual exposure region E2. In one embodiment, a ratio of the exposed area of the pixel-corresponding region 312 in the partial exposure process (i.e., the area of the dual exposure region E2) to the exposed area of the pixel-corresponding region 312 in the full exposure process (i.e., the total area of the single exposure region E1 and the dual exposure region E2) is about 0.3 to 0.7. In other words, the ratio of the area of the single exposure region E1 to the area of the dual exposure region E2 is about 3:7 to 7:3 (i.e., the ratio is about 0.428 to 2.333).

In one embodiment, in a unit area of the photo-alignment material layer 310 exposed to light, a total light exposure energy applied by the partial exposure process is larger than that of the full exposure process. For example, a light exposure intensity of the partial exposure process may be larger than that of the full exposure process, or a light exposure time of the partial exposure process may be longer than that of the full exposure process.

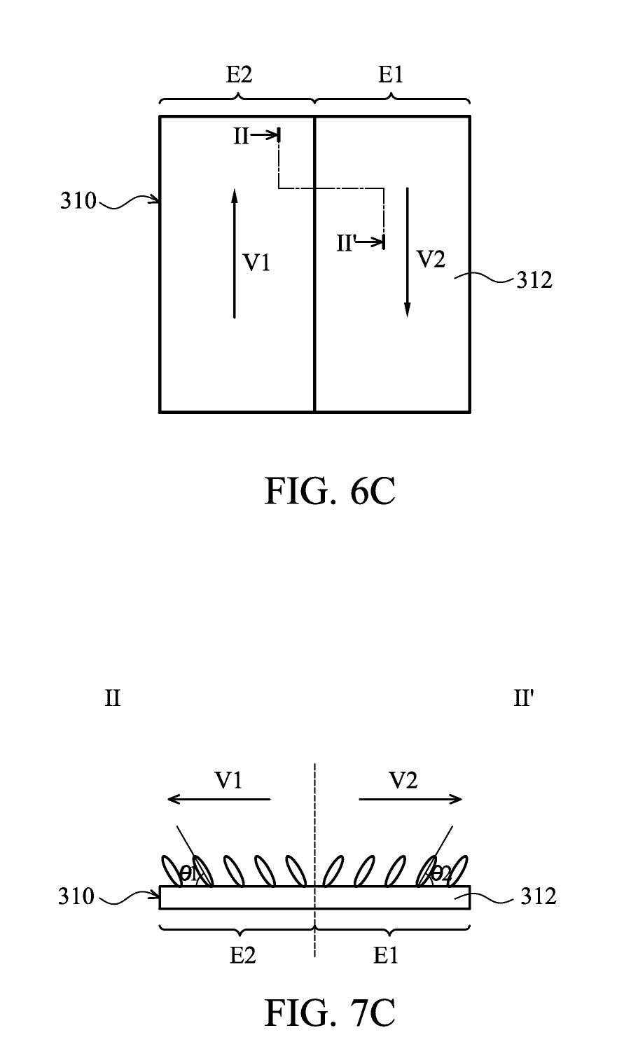

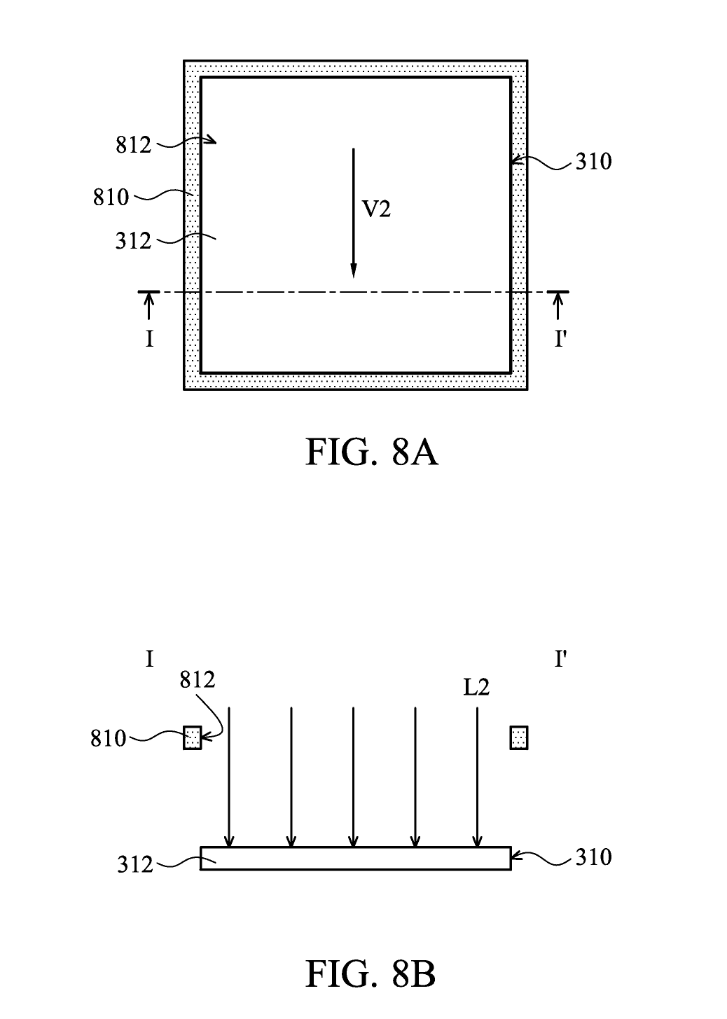

FIG. 8A is a top view of a manufacturing process of a photo-alignment film according to another embodiment of the disclosure. FIG. 8B is a cross-sectional view of the structure along the line I-I′ in FIG. 8A. In another embodiment, as shown in FIGS. 8A and 8B, the performing of the full exposure process may include disposing a photomask 810 on the pixel-corresponding region 312, wherein the photomask 810 has an opening 812 exposing the entirety of the pixel-corresponding region 312; and then, the entirety of the pixel-corresponding region 312 is exposed to light by using the photomask 810. The opening 812 may expose a plurality of pixel-corresponding regions at the same time, or may expose an entirety of the photo-alignment material layer 310.

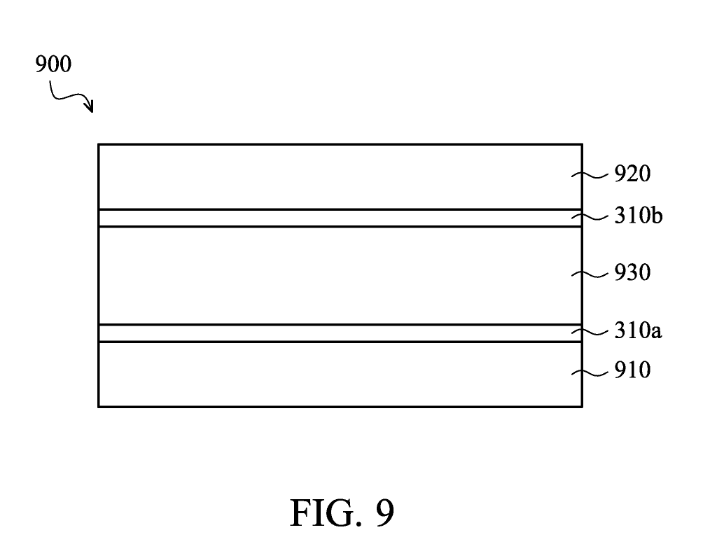

FIG. 9 is a cross-sectional view of a liquid crystal display according to an embodiment of the disclosure. As shown in FIG. 9, photo-alignment material layers 310a and 310b may respectively be formed on a first substrate 910 and a second substrate 920 of a liquid crystal display 900. Specifically, the liquid crystal display 900 includes the first substrate 910, the second substrate 920 opposite to the first substrate 910, and a liquid crystal layer 930 sandwiched between the first substrate 910 and the second substrate 920, wherein the photo-alignment material layer 310a is located between the first substrate 910 and the liquid crystal layer 930, and the photo-alignment material layer 310b is located between the second substrate 920 and the liquid crystal layer 930. The photo-alignment material layers 310a and 310b may align liquid crystal molecules (not shown) of the liquid crystal layer 930 for the liquid crystal molecules to have a first pre-tilt angle and a second pre-tilt angle, as shown in FIGS. 4C and 7C. The first substrate 910 may be one of a display substrate and an opposite substrate, and the second substrate 920 may be another one of the display substrate and the opposite substrate. In another embodiment, the photo-alignment material layer (not shown) may be only located on the first substrate 910 (or the second substrate 920).

In light of the foregoing, in the disclosure, a full exposure process and a partial exposure process may be used to replace the manufacturing method of a photo-alignment film known to the inventor (i.e., two partial exposure processes). The full exposure process of the disclosure can be performed without using any photomask, which can effectively reduce (or eliminate) the problem of misalignment and can significantly lower the manufacturing cost. Furthermore, in the disclosure, only two alignment regions respectively with substantially the same pre-tilt angle and different alignment directions may be formed on the pixel-corresponding region, which can improve the fast response of the liquid crystal molecules, which in turn, improves the display performance of the liquid crystal display.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A manufacturing method of a photo-alignment film, comprising:
providing a photo-alignment material layer having at least one pixel-corresponding region; and
performing a full exposure process and a partial exposure process with an alignment direction different from that of the full exposure process to the pixel-corresponding region,
wherein the full exposure process includes exposing an entirety of the pixel-corresponding region to light, and the partial exposure process includes exposing a portion of the pixel-corresponding region to light.

2. The manufacturing method of a photo-alignment film as claimed in claim 1, wherein the photo-alignment material layer has a photo-alignment material dominated by a second photo-alignment, and the performing of the full exposure process and the partial exposure process with the alignment direction different from that of the full exposure process to the pixel-corresponding region comprises:
performing the full exposure process to the pixel-corresponding region which is not exposed to light, such that the pixel-corresponding region has a first alignment direction; and
thereafter, performing the partial exposure process to the pixel-corresponding region, such that the portion of the pixel-corresponding region has a second alignment direction different from the first alignment direction.

3. The manufacturing method of a photo-alignment film as claimed in claim 1, wherein the photo-alignment material layer has a photo-alignment material dominated by a first photo-alignment, and the performing of the full exposure process and the partial exposure process with the alignment direction different from that of the full exposure process to the pixel-corresponding region comprises:
performing the partial exposure process to the pixel-corresponding region which is not exposed to light, such that the portion of the pixel-corresponding region has a first alignment direction; and
thereafter, performing the full exposure process to the pixel-corresponding region, such that the pixel-corresponding region, except the portion, has a second alignment direction different from the first alignment direction.

4. The manufacturing method of a photo-alignment film as claimed in claim 1, wherein the performing of the full exposure process comprises:
exposing the entirety of the pixel-corresponding region to light by using a photomask with an opening, wherein the opening exposes at least the entirety of the pixel-corresponding region.

5. The manufacturing method of a photo-alignment film as claimed in claim 1, wherein the performing of the partial exposure process comprises:
exposing the portion of the pixel-corresponding region to light by using a photomask with an opening, wherein the opening exposes the portion of the pixel-corresponding region.

6. The manufacturing method of a photo-alignment film as claimed in claim 1, wherein in a unit area of the photo-alignment material layer exposed to light, a total light exposure energy applied by the partial exposure process is larger than that of the full exposure process.

7. The manufacturing method of a photo-alignment film as claimed in claim 6, wherein a light exposure intensity of the partial exposure process is larger than that of the full exposure process.

8. The manufacturing method of a photo-alignment film as claimed in claim 6, wherein a light exposure time of the partial exposure process is longer than that of the full exposure process.

9. The manufacturing method of a photo-alignment film as claimed in claim 1, wherein the pixel-corresponding region processed by the full exposure process and the partial exposure process has a single exposure region exposed to light one time and a dual exposure region exposed to light two times, wherein the portion is located in the dual exposure region, and the photo-alignment material layer located in the single exposure region has a first alignment direction, and the portion has a second alignment direction different from the first alignment direction.

10. The manufacturing method of a photo-alignment film as claimed in claim 9, wherein the first alignment direction is opposite to the second alignment direction.

11. The manufacturing method of a photo-alignment film as claimed in claim 1, wherein a ratio of a light exposure area of the portion in the partial exposure process to a light exposure area of the full of the pixel-corresponding region in the full exposure process is 0.3 to 0.7.

12. The manufacturing method of a photo-alignment film as claimed in claim 1, wherein the providing of the photo-alignment material layer comprises:
forming the photo-alignment material layer on a first substrate of a liquid crystal display,
wherein the liquid crystal display comprises the first substrate, a second substrate opposite to the first substrate, and a liquid crystal layer sandwiched between the first substrate and the second substrate, and the photo-alignment material layer is located between the first substrate and the liquid crystal layer.
